(19) United States
(12) Patent Application Publication
(10) Pub. No.: US 2017/0198528 A1
(43) Pub. Date: Jul. 13, 2017

(54) CHEMICAL VAPOR DEPOSITION-MODIFIED POLYCRYSTALLINE DIAMOND

(71) Applicant: Halliburton Energy Services, Inc., Houston, TX (US)

(72) Inventors: Gagan Saini, The Woodlands, TX (US); Qi Liang, The Woodlands, TX (US)

(21) Appl. No.: 15/321,396

(22) PCT Filed: Aug. 1, 2014
(86) PCT No.: PCT/US2014/049474

§ 371 Date: Dec. 22, 2016

(51) Int. Cl. E21B 10/573; C23C 16/27; E21B 10/55

(52) U.S. Cl. CPC E21B 10/5735; E21B 10/55; C23C 16/278

(57) ABSTRACT

The present disclosure related to polycrystalline diamond (PCD) having chemical vapor deposition (CVD) deposits and to PCD elements and drill bits containing such CVD-modified PCD. The present disclosure further relates to method of forming such materials.

### TECHNICAL FIELD

The present disclosure relates to an abrasive tool making process, material, or composition, particularly with an inorganic material, and also to boring or penetrating the earth particularly with a diamond insert.

### BACKGROUND

Extreme temperatures and pressures are commonly encountered during earth drilling for oil extraction or mining purposes. Diamond, with its unsurpassed mechanical properties, can be the most effective material when properly used in a cutting element or abrasion-resistant contact element for use in earth drilling. Diamond is exceptionally hard, conducts heat away from the point of contact with the abrasive surface, and may provide other benefits in such conditions.

Diamond in a polycrystalline form has added toughness as compared to single-crystal diamond due to the random distribution of the diamond crystals, which avoids the particular planes of cleavage found in single-crystal diamond. Therefore, PCD is frequently the preferred form of diamond in many drilling applications. A drill bit cutting element that utilizes PCD is commonly referred to as a polycrystalline diamond cutter (PDC). Accordingly, a drill bit incorporating PCD cutting elements may be referred to as a PDC bit.

PCD elements can be manufactured in a press by subjecting small grains of diamond and other starting materials to ultrahigh pressure and temperature conditions. One PCD manufacturing process involves forming a PCD table directly onto a substrate, such as a tungsten carbide substrate. The process involves placing a substrate, along with loose diamond grains mixed with a catalyst, into a container or can. Then the container or can in placed in in a pressure transferring cell and subjected to a high-temperature, high-pressure (HTHP) press cycle. The high temperature and pressure and catalyst cause the small diamond grains to form into an integral PCD table intimately bonded to the substrate. It is useful to remove the catalyst prior to use of the PCD, however, because properties of the catalyst have a negative effect in many applications, such as drilling. Thus, the PCD may be leached to remove the catalyst binder from all or part of the PCD. However, the leaching process is likely to damage the substrate, particularly if the catalyst is removed near the substrate-PCD boundary. Leaching processes in which the substrate is completely removed result in PCD that is often difficult to attach to a new substrate or to a drill bit.

### BRIEF DESCRIPTION OF THE DRAWINGS

A more complete understanding of the present embodiments and advantages thereof may be acquired by referring to the following description taken in conjunction with the accompanying drawings, which show particular embodiments of the current disclosure, in which like numbers refer to similar components, and in which:

FIG. 1A illustrates a front view of a PCD table with CVD diamond deposits;

FIG. 1B illustrates a front view of an alternative PCD table with CVD diamond deposits;

FIG. 1C illustrates a front view of an alternative PCD table with CVD diamond deposits;

FIG. 2A illustrates a cross-sectional side view of a PCD table with CVD diamond deposits brazed to a substrate;

FIG. 2B illustrates a cross-sectional side vice of a PCD table with CVD diamond deposits that enter the substrate;

FIG. 3 illustrates an earth-boring drill bit containing a PCD element with a PCD disc containing CVD diamond deposits and brazed to a substrate;

FIG. 4 illustrates a method of forming a PCD table with CVD diamond deposits;

FIG. 5 illustrates a front view of a mask assembly with the pattern of FIG. 1A; and

FIG. 6 illustrates a method of attaching a PCD table with CVD diamond deposits to a cutter.

### DETAILED DESCRIPTION

The present disclosure relates to polycrystalline diamond (PCD), particularly thermally stable polycrystalline diamond (TSP), modified by chemical vapor deposition (CVD) to include additional diamond deposits (such deposits are also referred to herein as “CVD diamond”). The present disclosure further relates to PCD elements, such as cutters or erosion control elements in an earth-boring drill bit, containing such CVD-modified PCD. The disclosure further relates to earth-boring drill bits or other downhole tools containing such PCD elements. In addition, the disclosure relates to methods of placing additional diamond deposits formed using CVD on PCD as well as methods of attaching such PCD to a substrate.

In order to make PCD more thermally stable, metal catalyst (e.g. a material, such a substantially pure metal or an alloy, containing a Group VIII metal, such as cobalt, iron or nickel, or another catalyst metal, such as copper) used in the formation of the PCD may be leached from all or part of the PCD. If all or substantially all of the PCD has been leached, it may then be referred to as TSP. TSP may include some residual catalyst, but in some embodiments at least 70% of the metal catalyst originally in the PCD has been removed to form TSP. In other embodiments, at least 85%, at least 90%, at least 95%, or at least 99% of the metal catalyst originally in the PCD has been removed. In another embodiment, the TSP is thermally stable at temperatures of at least 750° C., or even 900° C., at atmospheric pressure. In still another embodiment, the TSP is formed using at least some non-metal catalyst, such as a non-metal catalyst with a coefficient of thermal expansion closer to that of diamond than typical metal catalysts. The non-metal catalyst may remain in the TSP. Non-metal catalysts include alkaline and alkaline earth carbonates, such as Li₂CO₃, Na₂CO₃, MgCO₃, SrCO₃, CaCO₃, K₂CO₃; alkaline and alkaline earth sulfates, such as Na₂SO₄, MgSO₄ and CaSO₄, and alkaline or alkaline earth hydrates, such as Mg(OH)₂, Ca(OH)₂.

TSP, however, is often difficult to attach to other materials, such as a substrate or the bit body of an earth-boring drill bit. For embodiment, poor wetting may interfere with attachment using traditional brazing processes.

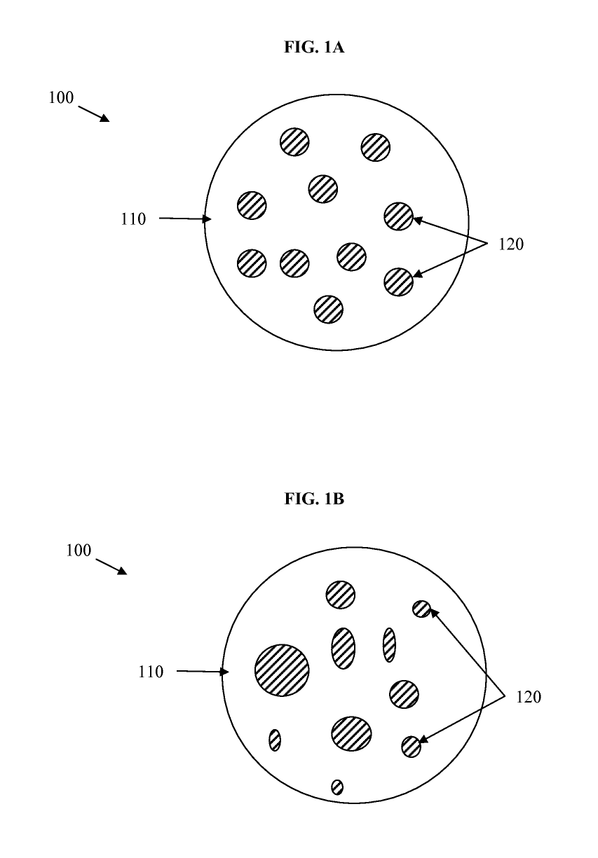

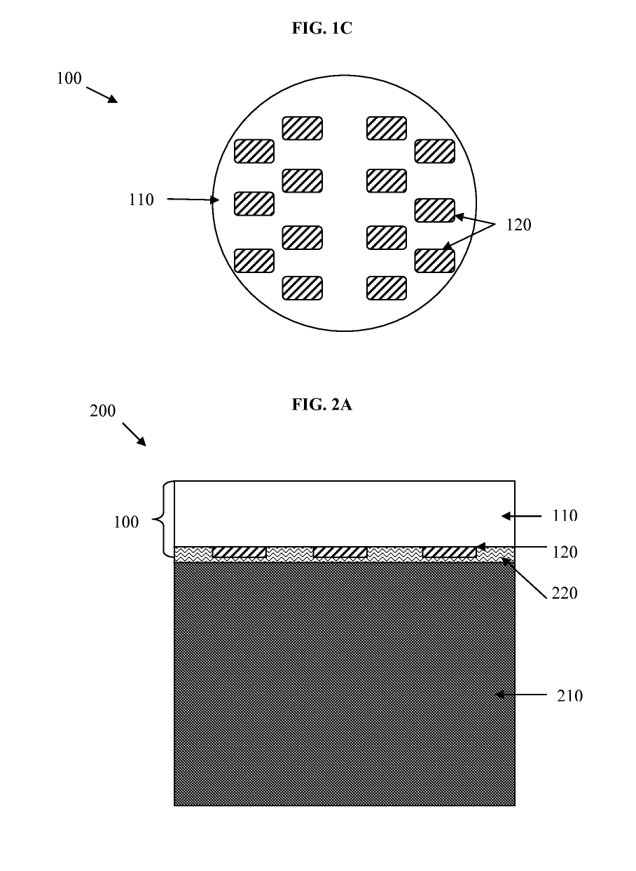

According to one embodiment, shown in FIG. 1, PCD table 100 may be formed containing both PCD 110 and CVD diamond 120. PCD table 100 may be wholly or partially TSP.

In one embodiment, CVD diamond 120 is substantially pure diamond. In another embodiment, CVD diamond 120 is doped with a dopant material to facilitate attachment to a brazing material. For embodiment, it may be doped with a brazing material or with a metal or an alloy.

In one embodiment, CVD diamond has a particular crystal orientation to facilitate attachment to a brazing material. For instance, it may be in a [100]>[111]> orientation.

In the embodiment shown in FIG. 1, the CVD diamond covers only a portion of the attachment surface of the PCD (the total surface that will eventually be attached to a substrate or a device, such as a drill bit; not the working surface). In more specific embodiments, it may cover no more than 10% of the attachment surface, no more than 25% of the attachment surface, no more than 50% of the attachment surface, or no more than 75% of the attachment surface.

In the embodiment shown in FIG. 1 A, CVD diamond 120 is deposited in an irregular pattern, in uniformly sized and shaped deposits. In the embodiment shown in FIG. 1B, CVD diamond 120 is deposited in an irregular pattern, in non-uniformly sized and shaped deposits. In the embodiment shown in FIG. 1C, CVD diamond 120 is deposited in a regular pattern in uniformly sized and shaped deposits. Although not shown, all combinations of regular and irregular patterns, uniform and non-uniform size, and uniform and non-uniform shape are possible for the CVD diamond. Regular sizes, shapes, and patterns may be more difficult to form, but may convey benefits such as resistance to forces in a particular direction, and could also help with management of residual stresses during subsequent attachment processes (for embodiment using brazing operations). In use, the PCD may be oriented to take advantage of the ability to resist forces in a particular direction. For embodiment, a cutter containing PCD with a regular CVD diamond pattern having 180 degree symmetry may be oriented in a bit such that the pattern resists forces applied to the working surface during use. Such a cutter may then be rotated 180 degrees when it begins to exhibit wear on the working surface.

CVD diamond 120 may be deposited in shapes that have a dimension in the plane of their attachment surface that varies from the micron scale to the millimeter or even centimeter scale.

CVD diamond 120 may be deposited in as many as hundreds or thousands of distinct deposits on PCD 110, or as few as three, five, ten, or twenty distinct deposits on PCD 110.

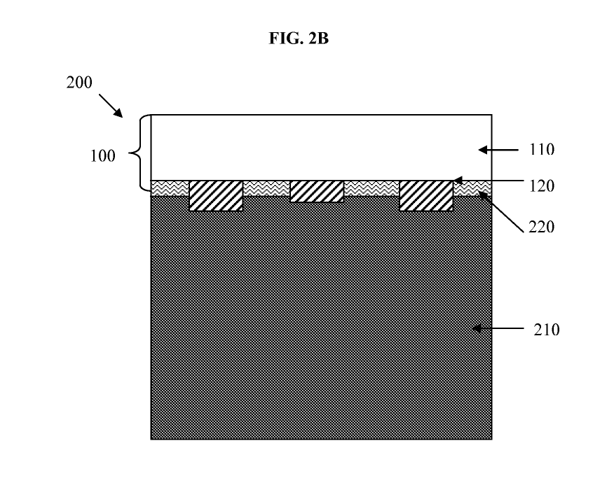

CVD diamond 120 may have a thickness or height above PCD 110 that is less than the optimal thickness of any braze material used to attach PCD table 100 to another object, such as a substrate or drill bit, as further described with respect to FIG. 2A. In other embodiments, CVD diamond 120 may have a thickness greater than the thickness of any brazing material and may fit in depressions in a substrate or bit, as further described with respect to FIG. 2B. In specific embodiments, the CVD diamond 120 has a thickness or height above PCD 110 that is between one thousands of an inch and ten thousands of an inch.

In general, CVD diamond 120 may be composed and deposited in a manner designed to enhance the total diamond surface area of PCD table 100 for brazing. It may also be deposited in a manner designed to enhance the mechanical interlock between PCD table 100 and a brazing material.

Referring to FIG. 2, PCD element 200 contains PCD table 100 attached to brazing material 220, which is further attached to substrate 210. According to one embodiment, substrate 210 includes a carbide, such as tungsten carbide. According to the embodiment shown in FIG. 2, PCD element 200 is a cutter for an earth-boring drill bit. In other embodiments, not shown, PCD table 100 may be brazed directly to a drill bit or other object. For instance, PCD table 100 may be an erosion-resistance element or a depth of cut control element.

Brazing material 220 may include only an active brazing material, only a non-active brazing material, or a combination of an active brazing material and a non-active brazing material. Brazing material 220 may be composed of any materials able to form a braze joint between PCD table 100 and substrate 210.

An active brazing material includes materials that readily form a carbide in the presence of carbon. Such a brazing material may exhibit improved abilities to overcome low wettability of diamond in the PCD 110 and possibly also in the CVD diamond 120 and to otherwise facilitate bonding of the brazing material to PCD table 100 as compared to non-active brazing materials.

Components of the active brazing material may react with carbon on the attachment surface of PCD 110 or CVD diamond 120 to form a layer of carbide which may then be brazed with a different brazing material, such as a non-active or more common brazing material. Active brazing materials may include alloys that of elements such as titanium, zirconium, vanadium, chromium, and manganese. More common, non-active brazing materials may include elements such silver, copper, nickel, gold, zinc, cobalt, iron, or palladium. In particular embodiments, the non-active brazing material includes manganese, aluminum, phosphorus, silicon, or zinc alloyed with nickel, copper, or silver.

As illustrated in FIG. 2A, CVD diamond 120 may have a height less than the thickness of brazing material 220.

As illustrated in FIG. 2B, CVD diamond may have a height greater than the thickness of brazing material 220 and may fit in corresponding depressions in substrate 210. This embodiment further provides additional mechanical interlock between PCD table 100 and substrate 210.

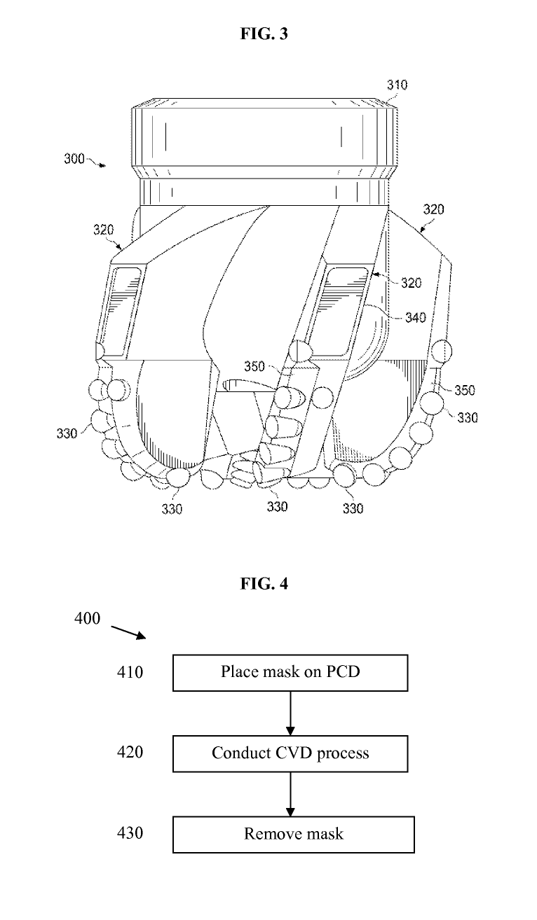

As illustrated in FIG. 3, PCD table 100 may be attached to an earth-boring drill bit, such as fixed cutter drill bit 300 containing a PCD element 330 in the form of a cutter. Fixed cutter drill bit 300 includes bit body 310 with a plurality of blades 320 extending therefrom. Bit body 310 may be formed from steel, steel alloys, a matrix material, or other suitable bit body material. Bit body 310 maybe formed to have desired wear, erosion, and other properties, such as desired strength, toughness, and machinability. PCD elements may be mounted on the bit as cutters or as elements other than cutters, such an erosion resistant elements or depth of cut control elements (not shown).

Blades 320 may include cutters 330. Although bit 300 is shown with multiple cutters 330 formed using CVD diamond, as few as one cutter may include CVD diamond. In a specific embodiment, a set of cutters 330 at corresponding locations on blades 320 may each include CVD diamond. In another embodiment, all gage cutters may include CVD diamond. In another embodiment, all non-gage cutters may include CVD diamond. In still another embodiment, all cutters 330 may include CVD diamond. In some embodiments, cutters including CVD diamond maybe selected due to locations where forces or stresses, such as shear stresses, better withstood by cutters including CVD diamond, are higher than at other cutter locations. Similarly, erosion resistant elements, depth of cut control elements, or other bit components formed from PCD may be selected to include CVD diamond in order to better withstand forces and stresses based on location.

For the embodiment shown in FIG. 3, fixed cutter drill bit 300 has five blades 320. For some applications the number of blades disposed on a fixed cutter drill bit incorporating teachings of the present disclosure may vary between four and eight blades or more. Respective junk slots 340 may be located between adjacent blades 320. The number, size and configurations of blades 320 and junk slots 340 may be selected to optimize flow of drilling fluid, formation cutting and downhole debris from the bottom of a wellbore to an associated well surface.

Drilling action associated with drill bit 300 may occur as bit body 310 is rotated relative to the bottom (not expressly shown) of a wellbore in response to rotation of an associated drill string (not expressly shown). At least some cutters 330 disposed on associated blades 330 may contact adjacent portions of a downhole formation (not expressly shown) during drilling. The inside diameter of an associated wellbore may be generally defined by a combined outside diameter or gage diameter determined at least in part by respective gage portions 350 of blades 330. The cutters 330 are oriented such that the PCD contacts the formation. In embodiments, such as that shown in FIG. 1C, where the CVD diamond 120 is deposited in a particular pattern, the PCD element may be oriented so that the pattern helps resist stresses or forces during drilling. If the pattern is symmetrical, the PCD element may be rotated when it becomes worn on at least one side.

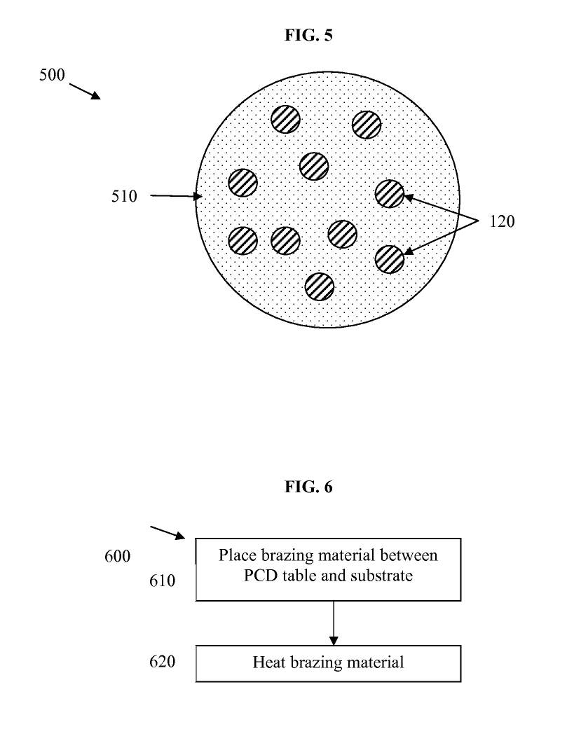

The present disclosure further relates to a method 400 of forming a PCD table with CVD diamond deposits as illustrated in FIG. 4. In step 410, a mask 510 is placed on PCD 110 (not shown), as further illustrated in FIG. 5. Mask 510 has a pattern which protects areas of PCD 110 from CVD diamond deposition, while allowing deposition in other areas. In step 420, a CVD process is conducted, such that CVD diamond 120 is deposited as shown in FIG. 5 in masked PCD assembly 500. The CVD process may be any process known to be able to deposit diamond.

In one embodiment, the CVD process is carried out by placing PCD 110 and mask 510 in the presence of a hydrocarbon gas in the presence of an energy source sufficient to cause deposition of diamond from the gas.

In some embodiments, the gas includes hydrogen gas, which removes non-diamond carbon during the CVD process. In one specific embodiment, the ratio of hydrocarbon gas to hydrogen gas is no more than 1:50, no more than 1:99, or no more than 1:200. In some embodiments, the hydrocarbon gas may consist essentially of methane.

In some embodiments, the CVD process is carried out at a pressure of 30 kPa or less, or 100 kPa or less.

In some embodiments, the energy source may be microwave power, a thermal source, such as a hot filament, an arc discharge, a welding torch, a laser, or an electron beam. In some embodiments, the CVD process is carried out at temperatures between 300° C. and 1000° C., more particularly between 300° C. and 700° C.

In some embodiments, the attachment surface of PCD 110, where mask 510 is placed, is cleaned or otherwise prepared for CVD prior to the CVD process. This cleaning or other preparation may occur before or after placement of mask 510.

Parameters of the CVD process, including preparation of the attachment surface of PCD 110, gasses used, mixture of gasses, pressure, energy source, and parameters of the energy source may be controlled to obtain a particular crystal orientation of CVD diamond 120.

In some embodiments, the CVD process may take place in a CVD chamber. If the chamber contains silicon or boron, these elements may be incorporated in CVD diamond 120.

Mask 510 may be formed from any material suitable for use in photolithography. However, some materials used in photolithography masks, such as metals or alloys, silicon dioxide, or boron-based materials, may result in incorporation of silicon, boron, or other elements in CVD diamond 120. One of ordinary skill in the art can select a suitable mask material based on whether incorporation of other elements in CVD diamond 120 is desirable or tolerable to be avoided and based on whether the material can tolerate the temperature and energy source in the selected CVD process. In general, CVD diamond 120 will not be deposited in such small deposits that edge effects or other small-scale-based complications of photolithography will be a concern.

In one embodiment, mask 510 may be formed from a particular material specifically so that material will be a dopant in CVD diamond 120 to facilitate brazing as discussed above or to confer other properties. CVD diamond 120 may also be doped using traditional methods, such as supplying dopant in the form of a gas, suhc as B₂H₆. SiH₄, or TiCl₄ during the CVD process.

In step 430, the mask 510 is removed from mask assembly 500. This may be accomplished through mechanical removal, or by chemically degrading mask 510. For embodiment, entire mask assembly 500 may simply be placed in a chemical able to dissolve mask 510 until it has been dissolved. Mechanical removal may be preferred if it can be accomplished without unacceptable levels of damage to mask 510, PCD 110, or CVD diamond 120 because it then allows reuse of mask 510.

FIG. 6 illustrates a method 600 of attaching a PCD table to a brazing material and substrate to form a PCD element, such as a cutter. First, in step 610, a brazing material is placed between the PCD table and the substrate. The brazing material may be provided in any form, but in particular embodiments it may be in the form of a thin foil or a wire or a paste.

Next, in step 620, the brazing material is heated to a brazing temperature to allow its attachment to both the PCD table and the substrate. For embodiment, the brazing temperature may be below 1,100-1,200° C., the graphitization point of TSP under controlled atmospheres. If the PCD table contains some PCD that is not TSP, the brazing temperature may be lower. The braze process also typically occurs at a temperature at which the brazing material is sufficiently molten and, in the case of active brazing materials, at which reaction with carbon on the surface of the PCD table may occur.

Once formed, the PCD element can then be attached to a drill bit via the substrate. Due to difference in materials properties such as wettability, a substrate is typically easier to bond to another surface than diamond is when using certain methods. For embodiment, a PCD element can be attached at its substrate to the drill bit via soldering or brazing, whereas PCD without a substrate could not be easily bonded to a drill bit with sufficient strength to withstand the conditions of drilling. Soldering and brazing may be performed at relatively low temperatures at which the PCD portion of the element remains stable, so that the PCD portion is not adversely affected by the process of joining to the bit. Alternatively, as discussed above the PCT table may be directly attached, for embodiment via soldering or brazing, to the drill bit without an intervening substrate.

In one specific embodiment, the disclosure provides a polycrystalline diamond (PCD) device including a substrate, a PCD table with a PCD table attachment surface, chemical vapor deposition (CVD) diamond deposited using CVD on the attachment surface in a pattern determined by a mask, and a brazing material attached to the PCD table attachment surface and a substrate attachment surface of the substrate. The CVD diamond may have a pre-selected crystal orientation. The CVD diamond may be doped. The PCD table may include thermally stable polycrystalline diamond (TSP). The brazing material may include an active brazing material. The brazing material may include a non-active brazing material.

In another specific embodiment, the disclosure provides a drill bit including a bit body, and a polycrystalline diamond (PCD) device. The polycrystalline diamond (PCD) device includes a substrate, a PCD table with a PCD table attachment surface, chemical vapor deposition (CVD) diamond deposited using CVD on the attachment surface in a pattern determined by a mask, and a brazing material attached to the PCD table attachment surface and a substrate attachment surface of the substrate. The CVD diamond may have a pre-selected crystal orientation. The CVD diamond may be doped. The PCD table may include thermally stable polycrystalline diamond (TSP). The brazing material may include an active brazing material. The brazing material may include a non-active brazing material.

In another specific embodiment, the disclosure provides a method of forming a polycrystalline diamond (PCD) device, by placing a mask on a PCD attachment surface or PCD, wherein the mask has a pattern, and conducting a chemical vapor deposition (CVD) process to deposit CVD diamond on the PCD in a pattern determined by the mask to form a PCD assembly including a PCD table having CVD diamond on the PCD attachment surface. The method may further include removing the mask from the PCD assembly to leave the PCD table. The method may further include placing a brazing material between the PCD attachment surface and a substrate attachment surface of a substrate, and heating the brazing material to a temperature sufficient to allow attachment of the brazing material to the PCD attachment surface and the substrate attachment surface to form a PCD element. The CVD process may include placing the PCD and mask in a chamber in the presence of hydrogen and a hydrocarbon gas, and supplying an energy source sufficient to cause deposition of diamond on the PCD. The CVD process may take place at a temperature between 300° C. and 1000° C. The CVD process may further include supplying a dopant source. The brazing material may include an active brazing material and heating includes heating to a temperature sufficient to allow the active brazing material to react with carbon on PCD attachment surface. The method may further include attaching the PCD table directly or via a substrate to a drill bit.

Although only exemplary embodiments of the invention are specifically described above, it will be appreciated that modifications and variations of these embodiments are possible without departing from the spirit and intended scope of the invention. For instance, the proper placement and orientation of PCD elements on other industrial devices may be determined by reference to the drill bit embodiment. Additionally, although PCD, the PCD table, and the PCD element shown in the FIGUREs are in the form of planar disc, non-planar surfaces and other shapes may be used. Further, although brazing is described as an embodiment method of attachment of the PCD table to a substrate or bit, other methods, such as soldering or welding, may also be used.

What is claimed is:

1. A polycrystalline diamond (PCD) device comprising:
a substrate;
a PCD table with a PCD table attachment surface;
chemical vapor deposition (CVD) diamond deposited using CVD on the PCD table attachment surface in a pattern determined by a mask; and
a brazing material attached to the PCD table attachment surface and a substrate attachment surface of the substrate.

2. The PCD device of claim 1, wherein the CVD diamond has a pre-selected crystal orientation.

3. The PCD device of claim 1, wherein the CVD diamond is doped.

4. The PCD device of claim 1, wherein the PCD table comprises thermally stable polycrystalline diamond (TSP).

5. The PCD device of claim 1, wherein the brazing material comprises an active brazing material.

6. The PCD device of claim 1, wherein the brazing material comprises a non-active brazing material.

7. A drill bit comprising:
a bit body; and
polycrystalline diamond (PCD) device, the PCD device including:
a substrate;
a PCD table with a PCD table attachment surface;
chemical vapor deposition (CVD) diamond deposited using CVD on the PCD table attachment surface in a pattern determined by a mask; and
a brazing material attached to the PCD table attachment surface and a substrate attachment surface of the substrate.

8. The bit of claim 7, wherein the CVD diamond has a pre-selected crystal orientation.

9. The bit of claim 7, wherein the CVD diamond is doped.

10. The bit of claim 7, wherein the PCD table comprises thermally stable polycrystalline diamond (TSP).

11. The bit of claim 7, wherein the brazing material comprises an active brazing material.

12. The bit of claim 7, wherein the brazing material comprises a non-active brazing material.

13. A method of forming a polycrystalline diamond (PCD) device, the method comprising:
placing a mask on a PCD attachment surface of a PCD table, wherein the mask has a pattern;
conducting a chemical vapor deposition (CVD) process to deposit CVD diamond on the PCD in a pattern determined by the mask to form a PCD assembly including a PCD table having CVD diamond on the PCD attachment surface;
removing the mask from the PCD attachment surface;
placing a brazing material between the PCD attachment surface and a substrate attachment surface of a substrate; and
heating the brazing material to a temperature sufficient to allow attachment of the brazing material to the PCD attachment surface and the substrate attachment surface to form a PCD device.

14. The method of claim 13, wherein the CVD process comprises:
placing the PCD and mask in a chamber in the presence of hydrogen and a hydrocarbon gas; and
supplying an energy source sufficient to cause deposition of diamond on the PCD.

15. The method of claim 13, wherein the CVD process takes place at a temperature between 300° C. and 1000° C.

16. The method of claim 13, wherein the CVD process further comprises supplying a dopant source.

17. The method of claim 13, wherein the brazing material comprises an active brazing material and heating comprises heating to a temperature sufficient to allow the active brazing material to react with carbon on PCD attachment surface.

18. The method of claim 13, further comprising attaching the PCD table via a substrate to a drill bit.

19. The PCD device of claim 2, wherein the pre-selected crystal orientation is a [100]>[111]>[110] orientation.

20. The drill bit of claim 8, wherein the pre-selected crystal orientation is a [100]>[111]>[110] orientation.
